(19) United States
(12) Patent Application Publication
(10) Pub. No.: US 2026/0076182 A1
(43) Pub. Date: Mar. 12, 2026

(54) VARIED SUBSTRATE THICKNESS FOR THERMAL MANAGEMENT

(71) Applicants: Abhishek A. Sharma, Portland, OR (US); Wilfred Gomes, Portland, OR (US); Tahir Ghani, Portland, OR (US)

(72) Inventors: Abhishek A. Sharma, Portland, OR (US); Wilfred Gomes, Portland, OR (US); Tahir Ghani, Portland, OR (US)

(21) Appl. No.: 18/828,193

(22) Filed: Sep. 9, 2024

(51) Int. Cl. H01L 23/36

(52) U.S. Cl. CPC H10W 40/10

(57) ABSTRACT

Integrated circuit (IC) structures with varied substrate thicknesses may enable targeted cooling in regions that are expected to generate more heat, while not excessively cooling regions that are expected to generate less heat. In one example, an IC structure includes a device region over a substrate, where the device region includes a first region (e.g., a region with high performance devices) and a second region coplanar with the first region (e.g., where the second region includes lower voltage transistors and/or other circuitry expect to generate less heat). In one example, the thickness of the substrate below the first region may be smaller than the thickness of the substate below the second region. In one example, a thermally conductive material over the second side of the substrate may be thicker below the first region, and thinner (or absent) below the second region.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity. The drive for the ever-increasing capacity, however, is not without issue. The necessity to optimize fabrication and performance of each component is becoming increasingly significant.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIGS. 1A-1H are cross-sectional diagrams of examples of IC structures including varied substrate thickness for thermal management, in accordance with some embodiments.

FIG. 2 is another a cross-sectional view of the IC structure of FIG. 1A, in accordance with an embodiment.

FIGS. 3A-3B are cross-sectional diagrams of example IC structures including varied substrate thickness for thermal management, in accordance with some embodiments.

FIG. 4 is a flow diagram of an example method for fabricating an IC structure including varied substrate thickness for thermal management, in accordance with some embodiments.

FIGS. 5-10 provide cross-sectional side views at various stages in the fabrication of an example IC structure according to the method of FIG. 4, in accordance with some embodiments.

FIG. 11 is a top view of a wafer and dies that may include any of the IC devices disclosed herein, in accordance with any of the embodiments disclosed herein.

FIG. 12 is a side, cross-sectional view of an IC package that may include any of the IC devices disclosed herein, in accordance with various embodiments.

FIG. 13 is a side, cross-sectional view of an IC device assembly that may include any of the IC devices disclosed herein, in accordance with any of the embodiments disclosed herein.

FIG. 14 is a block diagram of an example electrical device that may include any of the IC devices disclosed herein, in accordance with any of the embodiments disclosed herein.

### DETAILED DESCRIPTION

Disclosed herein are integrated circuit (IC) structures including varied substrate thicknesses for thermal management. The systems, methods and devices of this disclosure each have several innovative aspects, no single one of which is solely responsible for all desirable attributes disclosed herein. Details of one or more implementations of the subject matter described in this specification are set forth in the description below and the accompanying drawings.

IC structures may generate significant amounts of heat during operation. The trend towards smaller transistor sizes and high transistor density may lead to an increase in the power density (power per unit area) in an IC. Increased power density can lead to excessively hot spots on a die or other structure, which may lead to performance degradation, reliability issues, or even permanent damage to the IC. Therefore, effective thermal management can ensure the proper function and longevity of IC dies.

Thermal management techniques may involve the use of structures such as heat sinks to cool an IC and keep the temperature within acceptable limits. However, different regions of an IC may generate different amounts of heat during operation, which may prevent effective cooling with conventional techniques. For example, high performance transistors may operate at a higher voltage and may generate significantly more heat than transistors that operate at a lower voltage (e.g., low power or low voltage transistors). Additionally, certain types of circuitry, such as clock circuits, may generate more heat than other circuitry. Therefore, even with a heat sink, a die or other IC structure may develop hot spots that may affect reliability or performance. Furthermore, some circuitry, such as some thin film transistors, may suffer from poor performance at low temperatures. In such examples, some regions of a die may benefit from more cooling than other regions of the die.

In accordance with examples described herein, IC structures with varied substrate thicknesses may enable increased cooling in regions that are expected to generate more heat, while not excessively cooling regions that are expected to generate less heat. In one example, an IC structure includes a substrate with a first side and a second side opposite the first side, and a device region over the first side of the substrate, where the device region includes a first region (e.g., a region with high performance devices and/or other circuitry expected to generate more heat) and a second region coplanar with the first region (e.g., where the second region includes lower voltage transistors and/or other circuitry expect to generate less heat). In one example, the thickness of the substrate below the first region may be smaller than the thickness of the substate below the second region. In one such example, the IC structure may also include a thermally conductive material over the second side of the substrate, which may be thicker below the first region, and thinner (or absent) below the second region.

IC structures as described herein, in particular IC structures including varied substrate thicknesses for thermal management, may be implemented in one or more components associated with an IC or/and between various such components. In various embodiments, components associated with an IC include, for example, transistors, diodes, power sources, resistors, capacitors, inductors, sensors, transceivers, receivers, antennas, etc. Components associated with an IC may include those that are mounted on an IC or those connected to an IC. The IC may be either analog or digital and may be used in a number of applications, such as microprocessors, optoelectronics, logic blocks, audio amplifiers, etc., depending on the components associated with the IC. In some embodiments, IC structures as described herein may be included in a radio frequency IC (RFIC), which may, e.g., be included in any component associated with an IC of an RF receiver, an RF transmitter, or an RF transceiver, e.g., as used in telecommunications within base stations (BS) or user equipment (UE). Such components may include, but are not limited to, power amplifiers, low-noise amplifiers, RF filters (including arrays of RF filters, or RF filter banks), switches, upconverters, downconverters, and duplexers. In some embodiments, IC structures as described herein may be included in memory devices or circuits. In some embodiments, IC structures as described herein may be employed as part of a chipset for executing one or more related functions in a computer.

For purposes of explanation, specific numbers, materials, and configurations are set forth in order to provide a thorough understanding of the illustrative implementations. However, it will be apparent to one skilled in the art that the present disclosure may be practiced without the specific details and/or that the present disclosure may be practiced with only some of the described aspects. In other instances, well-known features are omitted or simplified in order not to obscure the illustrative implementations. The terms “substantially,” “close,” “approximately,” “near,” and “about,” generally refer to being within +/−10% of a target value, e.g., within +/−5% of a target value, based on the context of a particular value as described herein or as known in the art. Similarly, terms indicating orientation of various elements, e.g., “coplanar,” “perpendicular,” “orthogonal,” “parallel,” or any other angle between the elements, generally refer to being within +/−10% of a target value, e.g., within +/−5% of a target value, based on the context of a particular value as described herein or as known in the art.

In the following description, references are made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

In the drawings, while some schematic illustrations of example structures of various devices and assemblies described herein may be shown with precise right angles and straight lines, this is simply for ease of illustration, and embodiments of these assemblies may be curved, rounded, or otherwise irregularly shaped as dictated by, and sometimes inevitable due to, the fabricating processes used to fabricate semiconductor device assemblies. Therefore, it is to be understood that such schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication. Inspection of layout and mask data and reverse engineering of parts of a device to reconstruct the circuit using e.g., optical microscopy, TEM, or SEM, and/or inspection of a cross-section of a device to detect the shape and the location of various device elements described herein using, e.g., Physical Failure Analysis (PFA) would allow determination of presence of IC structures including varied substrate thicknesses for thermal management as described herein.

Various aspects of the illustrative implementations will be described using terms commonly employed by those skilled in the art to convey the substance of their work to others skilled in the art. For example, the terms “oxide,” “carbide,” “nitride,” “silicide,” etc. refer to compounds containing, respectively, oxygen, carbon, nitrogen, silicon, etc.; the term “high-k dielectric” refers to a material having a higher dielectric constant than silicon oxide; the term “low-k dielectric” refers to a material having a lower dielectric constant than silicon oxide. Materials referred to herein with formulas or as compounds cover all materials that include elements of the formula or a compound, e.g., TiSi or titanium silicide may refer to any material that includes titanium and silicon, WN or tungsten nitride may refer to any material that includes tungsten and nitrogen, etc. The term “insulating” means “electrically insulating,” the term “conducting” means “electrically conducting,” unless otherwise specified. Furthermore, the term “connected” may be used to describe a direct electrical or magnetic connection between the things that are connected, without any intermediary devices, while the term “coupled” may be used to describe either a direct electrical or magnetic connection between the things that are connected, or an indirect connection through one or more passive or active intermediary devices. A first component described to be electrically coupled to a second component means that the first component is in conductive contact with the second component (i.e., that a conductive pathway is provided to route electrical signals/power between the first and second components).

Various operations may be described as multiple discrete actions or operations in turn, in a manner that is most helpful in understanding the claimed subject matter. However, the order of description should not be construed as to imply that these operations are necessarily order dependent. These operations may not be performed in the order of presentation. Operations described may be performed in a different order from the described embodiment. Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges.

The description uses the phrases “in an embodiment” or “in embodiments,” which may each refer to one or more of the same or different embodiments. The terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The accompanying drawings are not necessarily drawn to scale. Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner. Although some materials may be described in singular form, such materials may include a plurality of materials, e.g., a semiconductor material may include two or more different semiconductor materials.

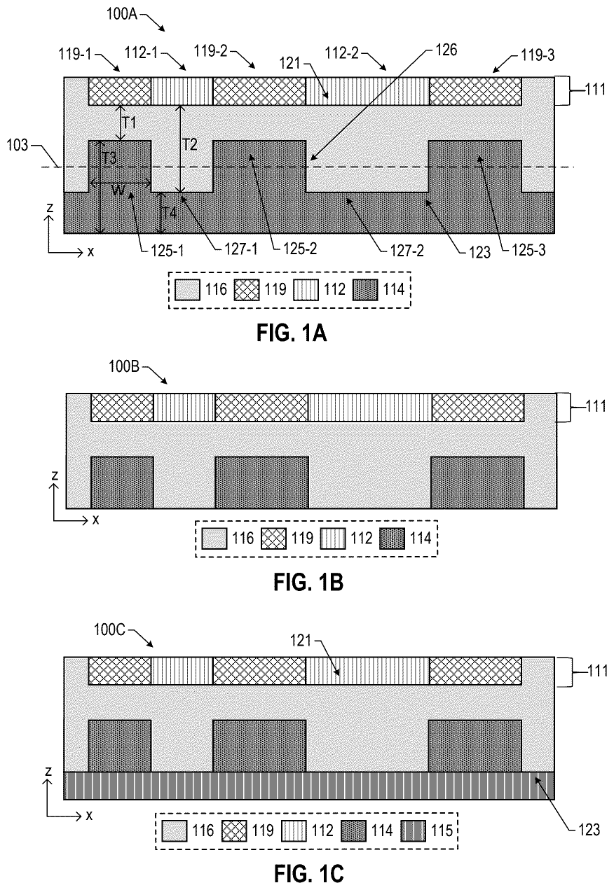

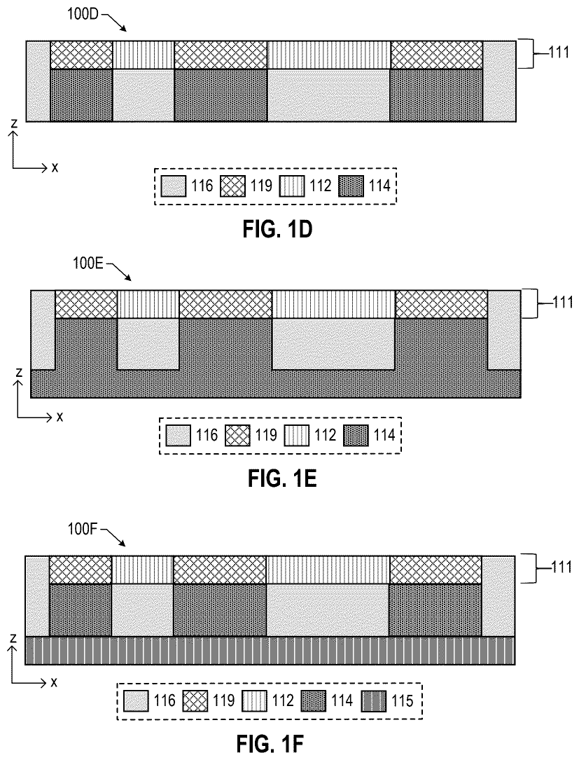

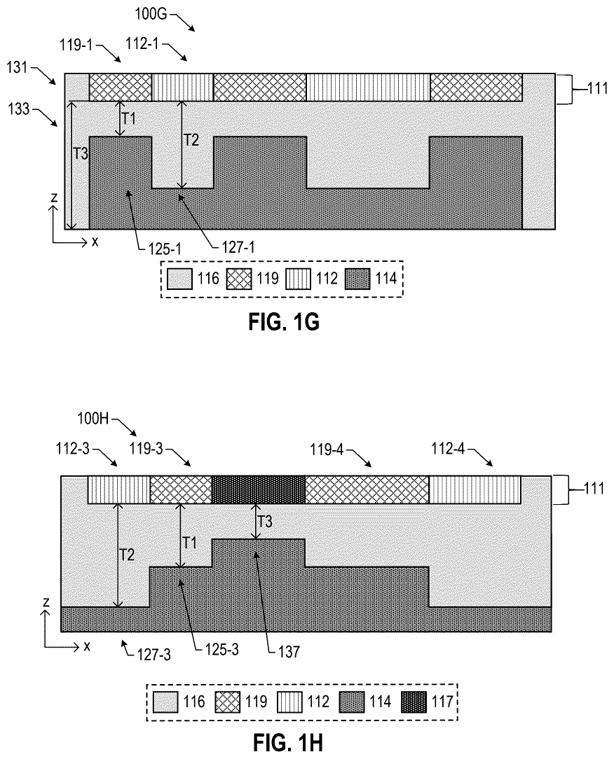

FIGS. 1A-1H are cross-sectional diagrams of examples of IC structures including substrates of varying thicknesses, in accordance with some embodiments. A number of elements referred to in the description of FIGS. 1A-1H, 2, 3A-3B, and 5-10, with reference numerals are illustrated in these drawings with different patterns, with a legend showing the correspondence between the reference numerals and patterns being provided at the bottom of each drawing page containing FIGS. 1A-1H, 2, 3A-3B, and 5-10. For example, the legend illustrates that FIGS. 1A-1H use different patterns to show a substrate 116 and a thermally conductive material 114, and so on.

The IC structures 100A-100H each include a substrate 116, where the substrate 116 has a first side 121 and a second side 123 opposite the first side 121. The IC structures 100A-100H include a device region 111 over the first side 121 and a thermally conductive material 114 over the second side 123. Therefore, the substrate 116 is between the device region 111 and the thermally conductive material 114. The first side of a substrate 116 on or over which a device layer or device region 111 is provided is typically referred to as a front side, and the other side (e.g., the second side 123) of the substrate 116 is referred to as a back side. Interconnect layers (e.g., a metallization stack) may be provided over the device region 111. The device region 111 includes devices formed over and/or in the substrate 116, and may include or be referred to as a front end of line (FEOL) layer. The device region 111 may include frontend devices (e.g., frontend transistors such as FinFETs, nanowire/nanoribbon transistors, frontend memory cells, or other frontend devices). Transistors of the device region may include transistors of any architecture, such as any non-planar or planar architecture. Non-planar transistors such as double-gate transistors, tri-gate transistors, FinFETs, and nanowire/nanoribbon/nanosheet transistors refer to transistors having a non-planar architecture. In comparison to a planar architecture where the transistor channel has only one confinement surface, a non-planar architecture is any type of architecture where the transistor channel has more than one confinement surface. A confinement surface refers to a particular orientation of the channel surface that is confined by the gate field. Non-planar transistors potentially improve performance relative to transistors having a planar architecture, such as single-gate transistors. Nanoribbon transistors may be particularly advantageous for continued scaling of complementary metal-oxide-semiconductor (CMOS) technology nodes due to the potential to form gates on all four sides of a channel material (hence, such transistors are sometimes referred to as “gate all around” transistors). Transistors of the device region 111 may include active regions formed based on the substrate 116 (e.g., from a silicon wafer or other semiconductor wafer), and/or thin film transistors in which the active region is formed from a thin semiconductor film deposited over the substrate 116.

The substrate 116 may be a semiconductor substrate composed of semiconductor material systems including, for example, N-type or P-type materials systems. In one implementation, the semiconductor substrate may be a crystalline substrate formed using a bulk silicon or a silicon-on-insulator (SOI) substructure. In other implementations, the semiconductor substrate may be formed using alternate materials, which may or may not be combined with silicon, that include, but are not limited to, germanium, silicon germanium, indium antimonide, lead telluride, indium arsenide, indium phosphide, gallium arsenide, aluminum gallium arsenide, aluminum arsenide, indium aluminum arsenide, aluminum indium antimonide, indium gallium arsenide, gallium nitride, indium gallium nitride, aluminum indium nitride or gallium antimonide, or other combinations of group III-V materials (i.e., materials from groups III and V of the periodic system of elements), group II-VI (i.e., materials from groups II and IV of the periodic system of elements), or group IV materials (i.e., materials from group IV of the periodic system of elements). In some embodiments, the substrate may be non-crystalline. In some examples, the substrate may be a glass substrate, or include a glass core. As used herein, the term “glass core” refers to a structure (e.g., a portion of a glass layer) of any glass material such as quartz, silica, fused silica, silicate glass (e.g., borosilicate, aluminosilicate, alumino-borosilicate), soda-lime glass, soda-lime silica, borate glass, lead borate glass, photosensitive glass, non-photosensitive glass, or ceramic glass. In particular, a glass core may be bulk glass or a solid volume/layer of glass, as opposed to, e.g., materials that may include particles of glass, such as glass fiber reinforced polymers. Such glass materials are typically non-crystalline, often transparent, amorphous solids. In some embodiments, a glass core may be an amorphous solid glass layer. In some embodiments, a glass core may include silicon and oxygen, as well as any one or more of aluminum, boron, magnesium, calcium, barium, tin, sodium, potassium, strontium, phosphorus, zirconium, lithium, titanium, and zinc. In some examples, the substrate may be a sapphire substrate. In other examples, the substrate 116 may be, or include, other suitable substrate materials.

The thermally conductive material 114 may be any suitable thermally conductive material, and may typically have a higher thermal capacity and/or lower thermal resistance than the material(s) of the substrate 116. In one example, the thermally conductive material 114 includes one or more of: a metal, oxygen, nitrogen, silicon, and carbon. In some examples, the thermally conductive material 114 may include one or more of: aluminum nitride, silicon carbide, aluminum oxide, germanium, copper, an alloy of copper and tungsten, aluminum silicon carbide, aluminum, and silver.

Referring again to the device region 111, the device region 111 may include regions 119 and 112 that are expected, during operation, to generate varying amounts of heat. For example, the regions 119 (individually labeled as regions 119-1, 119-2, and 119-3) are expected to generate relatively more heat than the regions 112 (which are individually labeled as regions 112-1 and 112-2). Although the examples in FIGS. 1A-1F illustrate IC structures in which different areas of the device region 111 are classified as either lower power regions (e.g., the regions 112) expected to generate less heat or higher power regions (e.g., the regions 119) expected to generate more heat, regions of an IC structure may be classified using a higher granularity to account for more than two regions. For example, FIGS. 1G and 1H illustrate example IC structures including three different regions expected to generate different amounts of heat.

The regions 119 of the device region 111 that are expected to generate significant heat may include, for example, particular types of transistors or circuitry that consume more power than the transistors or circuitry in the regions 112. Transistors that consume more or less power may have different dimensions and/or include different materials. For example, transistors in the regions 119 may have a channel length or gate length that is greater than the channel length or gate length of transistors in the regions 112. In another example, transistors in the regions 119 may also, or alternatively, have a thinner gate dielectric layer than transistors in the regions 112. In another example, the transistors in the regions 119 may also, or alternatively, have source or drain regions with a higher doping concentration than transistors in the regions 112. In one example, the regions 119 may include a higher density of devices than the regions 112. In one example, the regions 119 may include circuitry that consumes more power than other circuitry on the die. Examples of circuitry that may consume significant power include clock circuitry (e.g., one or more oscillators, phase locked loop (PLLs), clock multiplexer circuitry, clock distribution networks, and/or other clock circuitry), compute logic, and memory (e.g., SRAM, DRAM, or other memory circuitry).

Referring to the example illustrated in FIG. 1A, the substrate 116 of the IC structure 100A includes portions 125-1, 125-2, and 125-3 below and aligned with the regions 119 in which the substrate 116 has been thinned relative to portions 127-1 and 127-2 below and aligned with the regions 112. For example, a first portion 125-1 of the substrate below a first region 119-1 has a first thickness T1 (e.g., where the first thickness T1 is a dimension of the substrate 116 in a plane substantially orthogonal to the substrate 116, along the z-axis as illustrated in FIG. 1A). A second portion 127-1 of the substrate 116 below a second region 112-1 has a second thickness T2 (e.g., where the second thickness T2 is a dimension of the substrate 116 in a plane substantially orthogonal to the substrate). In the example illustrated in FIG. 1A, the second thickness T2 is greater than the first thickness T1 (e.g., the first thickness T1 is smaller than the second thickness T2). In various examples, a ratio of the first thickness T1 to the second thickness T2 is in a range of about 0.2:1 to 0.9:1 (e.g., the thickness T1 is about 20-90%, about 5-90%, or about 30-80% of the thickness T2). In some examples, the difference in thicknesses (e.g., the difference between T1 and T2), may be at least about 50 nanometers, at least about 100 nanometers, or at least about 400 nanometers. Thus, the difference in thicknesses is greater than differences that may be present due to imperfections in the polish process. In some examples, the difference in thicknesses may be on the order of tens of micrometers. The thinned areas (e.g., openings) may also include sidewalls 126 resulting from the removal of material from the substrate 116.

As a result of the thinned substrate regions, the thermally conductive material 114 over the second side 123 of the substrate 116 is closer to the regions 119 than to the regions 112. For example, the region 119-1 is a first distance from the thermally conductive material 114 (where the first distance is equal to about the thickness T1 as shown in FIG. 1A), the second region 112-1 is a second distance from the thermally conductive material 114 (where the second distance is equal to about the thickness T2 as shown in FIG. 1A), and the first distance is different from (e.g., less than) the second distance. Thus, in the plane 103 (where the plane 103 is substantially parallel to the substrate 116 and the x-y plane as shown in FIG. 1A, where the y-axis is going into and coming out of the page), the IC structure 100A includes portions of the thermally conductive material 114 aligned with the regions 119 and portions of the substrate 116 (e.g., a semiconductor material or other material of the substrate 116) aligned with the regions 112. In one example in which the substrate includes a semiconductive material, in the plane 103, a continuous portion of a thermally conductive material 114 below the first region 119-1 is between portions of the semiconductor material.

The example illustrated in FIG. 1A depicts a device region 111 that includes three regions 119 and two regions 112 (where, in the depicted example, the different regions are alternating). For example, the region 119-2 is between the regions 112-1 and 112-2, where the portions of the substrate under the regions 112-1 and 112-2 have the thickness T1, and the portion of the substrate 116 under the region 119-2 has the thickness T2. In the example illustrated in FIG. 1A, although the thicknesses of the thermally conductive material 114 varies below the different regions 119 and 112, the thermally conductive material 114 is present below both the regions 119 and 112. For example, the thermally conductive material 114 has a third thickness T3 in a plane intersecting the first region 119-1 (e.g., directly below the first region 119-1) and the thermally conductive material 114 has a fourth thickness T4 in a plane intersecting the second region 112-1 (e.g., directly below the second region 112-1), where the third thickness T3 is greater than the fourth thickness T4. In the example illustrated in FIG. 1A, the first thickness T1 plus the third thickness T3 is substantially equal to the second thickness T2 plus the fourth thickness T4.

In other examples, the thermally conductive material 114 may be present below some regions and absent under other regions. For example, FIG. 1B illustrates an IC structure 100B in which the thermally conductive material 114 is present below the regions 119, and absent below the regions 112 (e.g., substantially absent from a portion below the substrate 116 aligned with the regions 112).

FIG. 1C illustrates an example IC structure 100C that includes two thermally conductive materials over the second side of the substrate. For example, the IC structure 100C includes a first thermally conductive material 114 and a second thermally conductive material 115 below the thermally conductive material 114. Thus, in the example illustrated in FIG. 1C, the thermally conductive material 114 is between the second thermally conductive material 115 and the device region 111 (and in the example illustrated in FIG. 1C, between the second thermally conductive material 115 and the substrate 116). In one example, the first thermally conductive material 114 has one or more of: a different material composition, a different thermal capacity, and a different thermal resistance relative to the second thermally conductive material. In one example, the first thermally conductive material 114 has a higher thermal capacitance or capacity relative to the second thermally conductive material 115. In one example, the second thermally conductive material 115 has a lower thermal resistance relative to the thermally conductive material 114. Thus, in one such example, the thermally conductive material 114 may be able to quickly reduce the heat from the regions 119 (e.g., thermal spreading), which may result in a more uniform heat distribution. The second thermally conductive material 115 may then enable heat transfer from the more uniformly heated layer of the thermally conductive material 114.

In some examples in which the thermally conductive material 114 is not an electrically conductive material, portions of the substrate may be completely removed and filled with the thermally conductive material 114. For example, FIGS. 1D-1F illustrate examples in which the substrate is recessed all the way to the device region, so that the original substrate material is substantially absent between the regions 119 and the thermally conductive material 114. FIG. 1D illustrates an example IC structure 100D in which the thermally conductive material 114 is below the regions 119 and absent from below the regions 112. The FIG. 1E illustrates an example IC structure 100E that is similar to the IC structure 100D in that portions of the substrate 116 have been removed and replaced with the thermally conductive material 114. However, the IC structure 100E differs from the IC structure 100D in that the thermally conductive material 114 is present under both the regions 119 and the regions 112 (with different thicknesses). FIG. 1F illustrates another example IC structure 100F that is similar to the IC structure 100D in that portions of the substrate 116 have been removed and replaced with the thermally conductive material 114, with an additional layer of another thermally conductive material 115 below the thermally conductive material 114. Thus, in the example illustrated in FIG. 1F, a continuous portion of the first thermally conductive material 114 is between the device region 111 and the second thermally conductive material 115.

FIGS. 1G and 1H illustrate examples in which the substrate three different thicknesses. For example, FIG. 1G illustrates an example IC structure 100G that includes a third region 131 over the substrate 116 and coplanar with the first region, where a third portion 133 of the substrate 116 has a third thickness T3 below the third region 131 (where the third thickness T3 is a dimension of the substrate 116 in a plane substantially orthogonal to the substrate), and the third thickness T3 is different from (e.g., greater than) the second thickness and different from (e.g., greater than) the first thickness. In one such example, the third region 131 may be a region that lacks transistors (e.g., on the periphery of the device region 111). FIG. 1H illustrates another example IC structure 100H that includes a third region 117 that is expected to generate more heat than adjacent regions 119-3, 119-4, which are expected to generate more heat than the regions 112-3, 112-4. Thus, the region 117 represents a potential hot spot region on the IC structure 100H, with a gradient of cooler regions further from the hot spot region. In the example illustrated in FIG. 1H, the substrate 116 of the IC structure 100H includes a portion 125-3 having a thickness T1, a portion 127-3 having a thickness T2, and a portion 137 having a third thickness T3, where the third thickness is different (e.g., smaller) than both the first thickness T1 and the second thickness T2. In one such example, the region 119-3 includes first circuitry, the region 112-3 includes second circuitry, and the region 117 includes third circuitry, where the first, second, and third circuitry may be different from one another, and where the third circuitry generates more heat than the first or second circuitry.

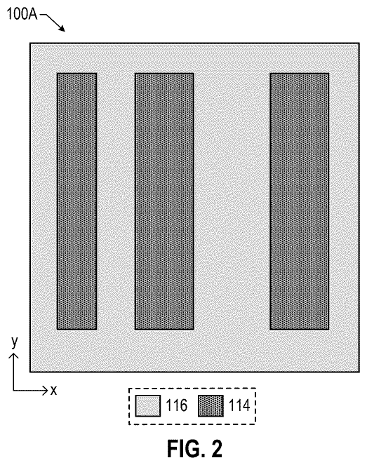

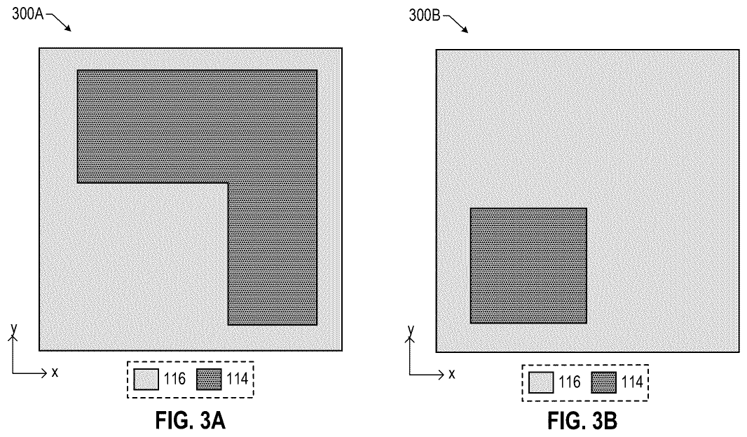

FIG. 2 is a cross-sectional view of the IC structure 100A of FIG. 1A along a plane 103 shown in FIG. 1A (e.g., along the x-y plane). In the example illustrated in FIG. 2, portions of the thermally conductive material 114 may be between portions of the substrate 116 along the plane 103 (e.g., along the x-axis as shown in FIG. 2). FIG. 2 illustrates an example in which the portions of the thermally conductive material 114 have a substantially rectangular cross-section and extend across the IC structure 100A along the y-axis; however, the recessed regions of the second side 123 of the substrate may have a variety of cross-sectional shapes (e.g., square, hexagonal, L-shaped, round, etc.) and sizes. Thus, the portions of thermally conductive material 114 in the recessed regions of the substrate 116 may have a variety of cross-sectional shapes and sizes. FIGS. 3A and 3B illustrate two examples of IC structures 300A and 300B that include recessed regions filled with the thermally conductive material 114, where the regions have different cross-sectional shapes. FIG. 3A illustrates an example in which an L-shaped region (e.g., a region with a cross-section that is substantially L-shaped) of the substrate 116 is thinned and filled with the thermally conductive material 114. FIG. 3B illustrates an example in which a substantially square-shaped region (e.g., a region with a cross-section that is substantially square) of the substrate 116 is thinned and filled with the thermally conductive material 114. In one example, the recessed regions of the substrate 116 may be substantially aligned with regions of circuitry in the device region 111. In one example, the minimum width of a region of the thermally conductive material 114 may be about 100 nanometers, and the maximum width may be the width of the die or other IC structure, where the width is a dimension of the thermally conductive material 114 in a plane substantially parallel to the substrate 116. Other shapes and sizes of recessed regions of the substrate are possible. Although FIGS. 3A and 3B depict only a single region of the thermally conductive material 114 and FIG. 2 depicts three regions of the thermally conductive material 114, other numbers and arrangements of recessed regions of the substrate are possible.

Thus, FIGS. 1A-1H, 2, and 3A-3B illustrate example IC structures in which a substrate is thinned from a second side (e.g., a back side) and filled with a thermally conductive material, which can enable targeted cooling based on expected heat generation in different regions of the device region. The various features of the IC structures discussed above may be combined (e.g., a second thermally conductive material 115 may be in any of the embodiments).

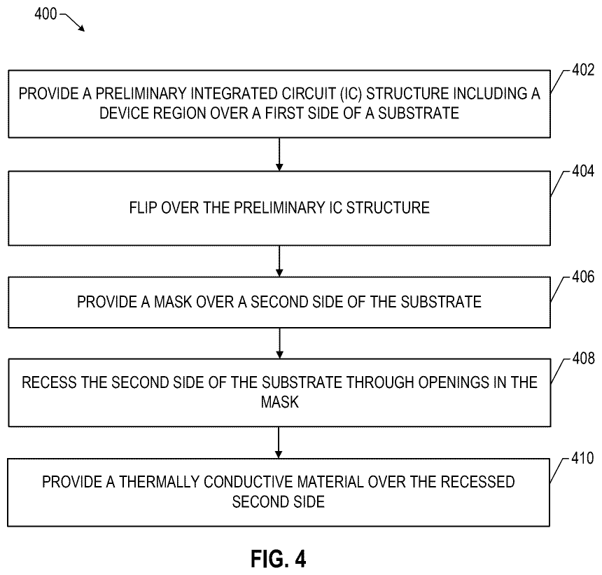

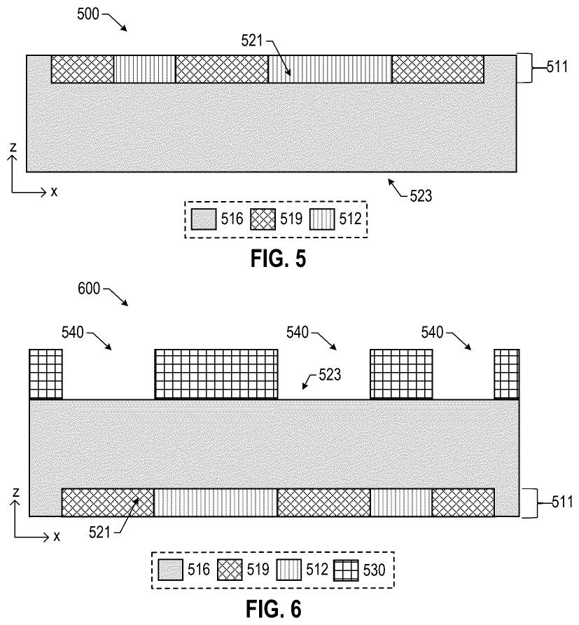

FIG. 4 is a flow diagram of an example method 400 for fabricating an IC structure including varied substrate thickness for thermal management. FIGS. 5-10 provide different views at various stages in the fabrication of an example assembly according to the method of FIG. 4, in accordance with some embodiments. Although the operations of the method of FIG. 4 are illustrated once each and in a particular order, the operations may be performed in any suitable order and repeated as desired. For example, one or more operations may be performed in parallel to fabricate multiple IC structures including varied substrate thickness for thermal management substantially simultaneously. In another example, the operations may be performed in a different order to reflect the structure in which varied substrate thicknesses for thermal management will be implemented.

In addition, the example fabricating method of FIG. 4 may include other operations not specifically shown in FIG. 4, such as various cleaning or planarization operations as known in the art. For example, in some embodiments, a support, as well as layers of various other materials subsequently deposited thereon, may be cleaned prior to, after, or during any of the processes of the methods described herein, e.g., to remove oxides, surface-bound organic and metallic contaminants, as well as subsurface contamination. In some embodiments, cleaning may be carried out using e.g., chemical solutions (such as peroxide), and/or with ultraviolet (UV) radiation combined with ozone, and/or oxidizing the surface (e.g., using thermal oxidation) then removing the oxide (e.g., using hydrofluoric acid (HF)). In another example, the intermediate IC structures described herein may be planarized prior to, after, or during any of the processes of the method of FIG. 4 described herein, e.g., to remove overburden or excess materials. In some embodiments, planarization may be carried out using either wet or dry planarization processes, e.g., planarization be a chemical mechanical planarization (CMP), which may be understood as a process that utilizes a polishing surface, an abrasive and a slurry to remove the overburden and planarize the surface.

Turning to FIG. 4, the method 400 begins with a process 402 of providing a preliminary IC structure including a device region over a first side of a substrate. The IC structure 500 of FIG. 5 is an example resulting IC structure of the process 402. The IC structure 500 includes a device region 511 over a first side 521 of a substrate 516. The device region may include different portions or regions 519 and 512. The device region 511 and regions 519, 512 may be examples of the device region 111 and the regions 119, 112, discussed above. The substrate 516 may be an example of the substrate 116, discussed above. The substrate has a second side 523 opposite the first side 521. In one example, the first side 521 is a front side of the substrate 516 and the second side 523 is a back side of the substrate 516.

The method 400 continues with a process 404 of flipping over the preliminary IC structure and the process 406 of providing a mask over a second side of the substrate. The IC structure 600 of FIG. 6 is an example resulting IC structure of the processes 404 and 406. As can be seen in FIG. 6, the IC structure 500 from FIG. 5 has been flipped over to expose the second side 123 of the substrate 516. A mask 530 has been provided over the second side 523 of the substrate. The mask 530 may be provided according to any suitable technique and include any suitable mask material. The mask 530 covers some portions of the substrate (e.g., portions aligned with the regions 512) and includes openings 540 that expose other portions of the substrate (e.g., portions aligned with the regions 519).

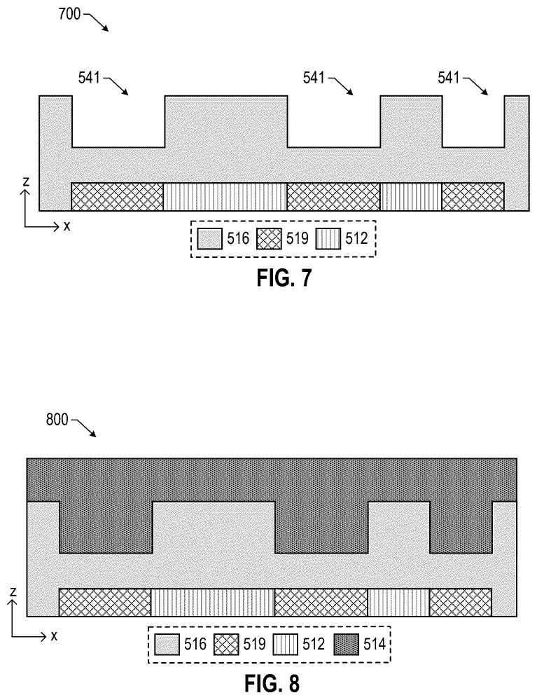

The method 400 continues with a process 408 of recessing the second side of the substrate through openings in the mask. The IC structure 700 of FIG. 7 is an example resulting IC structure of the process 408. The IC structure 700 includes recessed regions (e.g., openings 541) in the substrate 516. Any suitable etching technique, e.g., a dry etch, such as e.g., radio frequency (RF) reactive ion etch (RIE) or inductively coupled plasma (ICP) RIE may be used to form the openings 541 in the substrate 516. In some examples, the material of the substrate (e.g., a semiconductor material and/or other materials, as mentioned above) may be thinned (e.g., to a thickness in a range of 100 nanometers to 100 micrometers) in areas aligned with the regions 519, or entirely removed in the areas aligned with the regions 519. In some examples, additional masking may be performed in order to form further openings (e.g., to achieve more than two different substrate thicknesses, such as shown in FIGS. 1G and 1H). In one such example, after recessing the second side 523 and prior to providing a thermally conductive material, the method may involve providing a second mask over the second side 523 (e.g., where the second mask includes further openings), and recessing the second side 523 of the substrate 516 through the further openings in the second mask.

The method 400 continues with a process 410 of providing a thermally conductive material over the recessed second side of the substrate. The IC structure 800 of FIG. 8 is an example resulting IC structure of the process 410. The IC structure 800 includes the thermally conductive material 514 in the openings 541 (e.g., in the recesses regions of the substrate 516) and over the non-recessed regions of the substrate 516. Thus, in the example illustrated in FIG. 8, the layer of the thermally conductive material 514 is over substantially the entire second side 523 of the substrate 516. In the example illustrated in FIG. 8, the thermally conductive material 514 is thicker in or over the recessed regions of the substrate 516 (e.g., the regions of the substrate 516 directly over (or directly under when viewed with the first side 521 up) the regions 519) than over the non-recessed regions of the substrate (e.g., the regions of the substrate 516 directly over (or directly under when viewed with the first side 521 up) the regions 512 of the device region 511). The thermally conductive material 514 may include any suitable thermally conductive material, such as any of those described above, and may be deposited in the process 410 using a technique such as atomic layer deposition (ALD), chemical vapor deposition (CVD), plasma enhanced CVD (PECVD), or/and physical vapor deposition (PVD) processes such as sputter. In some examples, the thermally conductive material 514 may be thinned (e.g., via a polish or other suitable technique) to achieve the desired thickness over both the regions 512 and 519. In some examples, the thermally conductive material 514 may be thinned to the thermally conductive material 514 over the regions 512 (e.g., as illustrated in FIGS. 1D and 1F).

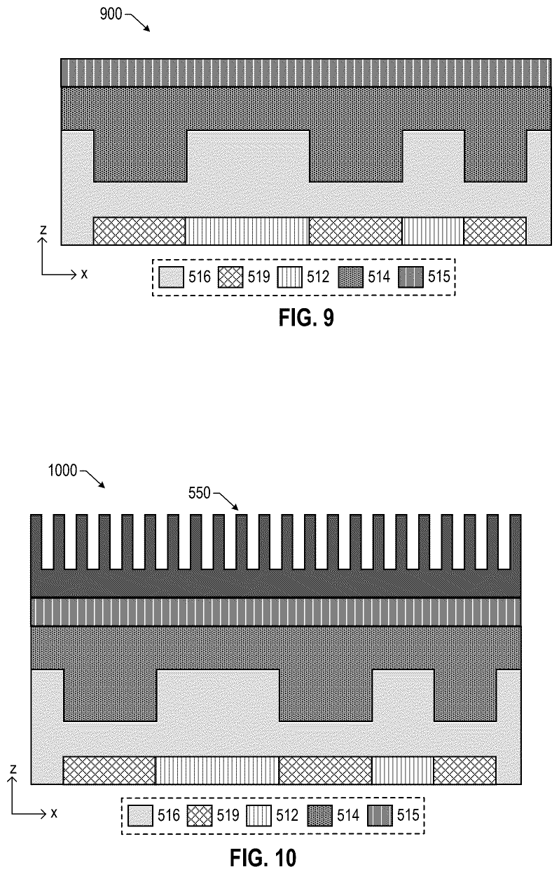

The method may continue with providing a further thermally conductive material over the second side of the substrate. The IC structure 900 of FIG. 9 is an example resulting IC structure of the process of providing a further thermally conductive material. As can be seen in FIG. 9, a first thermally conductive material 514 is present over the second side 523 of the substrate 516, and a second thermally conductive material 515 is present over the first thermally conductive material 514. The thermally conductive material 515 may include any suitable thermally conductive material, such as any of those described above, and may be deposited using a technique such as those described above with respect to the process 410. In one example, the second thermally conductive material 515 may have a substantially uniform thickness over the IC structure 900 (unlike the thermally conductive material 514, which has different thicknesses over the different regions 512 and 519).

The IC structure may, in a later process, be coupled with a heat sink. In one such example, the heat sink may be coupled with (e.g., in contact with, for example, in direct contact with) one of the thermally conductive materials provided over the second side of the substrate. The IC structure 1000 of FIG. 10 is an example IC structure that includes a heat sink coupled with the thermally conductive material over the second side of the substrate. As can be seen in FIG. 10, a heat sink 550, which typically includes one or more metals or other suitable thermally conductive material, is coupled with the second thermally conductive material 515. In examples where the second thermally conductive material 515 is absent, the heat sink 550 may be coupled with the thermally conductive material 514 (e.g., from the back side of the IC structure 900).

Thus, FIG. 4 illustrates a method 400 for fabricating an IC structure including a substrate with varying thicknesses. Performing the method 400 may result in several features in the final IC structure that are characteristic of the use of the method 400. For example, one such feature characteristic of the use of the method 400 is illustrated in the IC structure 800 shown in FIG. 8, in which the IC structure includes a device region 511 including a first portion or region 519 (e.g., with first transistors or circuitry) and a second portion or region 512 (e.g., with second transistors or circuitry, where the second transistors or circuitry have one or more different properties relative to the first transistors or circuitry). The IC structure includes a first layer including a thermally conductive material (e.g., below the device region when viewed with the front side of the IC structure up), and a second layer including a semiconductor material (e.g., a semiconductor material of the substrate 516) between the device region 511 and the first layer, where the first region 519 is a first distance from the layer of thermally conductive material 514, the second region 512 is a second distance from the layer thermally conductive material 514, and the first distance is different from the second distance. In one such example, the layer of semiconductor material has a first thickness between the first region 519 and the thermally conductive material 514 and a second thickness between the second region and the thermally conductive material 514 (where the first thickness is a dimension of the semiconductor material in a first plane substantially orthogonal to the device region 511, and the second thickness is a dimension of the semiconductor material in a second plane substantially orthogonal to the device region 511). In one example, the second thickness is about 20-90% greater than the first thickness. Another such feature characteristic of the use of the method 400 is illustrated in the IC structures 900 shown in FIGS. 9 and 1000 shown in FIG. 10, in which the IC structures 900 and 1000 include a further layer of another thermally conductive material 515, where the first thermally conductive material 514 is between the device region 511 and the second thermally conductive material 515.

IC devices and IC structures including a substrate with varying thicknesses as described herein (e.g., as described with reference to FIGS. 1A-1H, 2, 3A-3B, 4, and 5-10) may be used to implement any suitable components. For example, in various embodiments, IC devices described herein may be part of one or more of: a central processing unit, a memory device (e.g., a high-bandwidth memory device), a memory cell, a logic circuit, input/output circuitry, a field programmable gate array (FPGA) component such as an FPGA transceiver or an FPGA logic, a power delivery circuitry, an amplifier (e.g., a III-V amplifier), Peripheral Component Interconnect Express (PCIE) circuitry, Double Data Rate (DDR) transfer circuitry, a computing device (e.g., a wearable or a handheld computing device), a system including one or more of the aforementioned devices, etc.

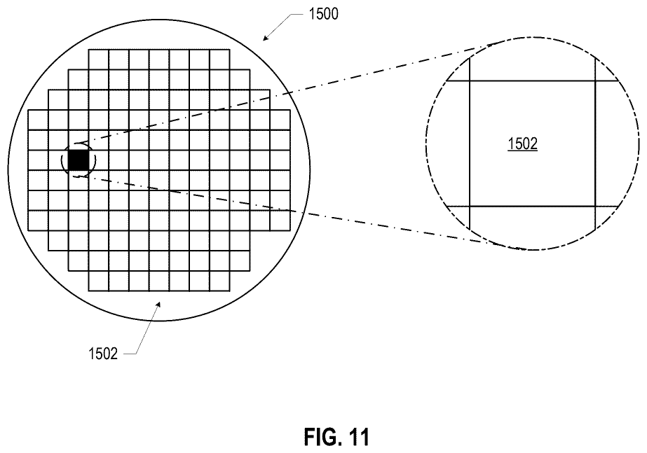

The IC structures disclosed herein, e.g., the IC structures 100A, 100B, 100C, 100D, 100E, 100F, 100G, 100H, 300A, 300B, 800, 900, 1000, or any variations thereof, may be included in any suitable electronic component. FIGS. 11-14 illustrate various examples of apparatuses that may include any of the IC structures or assemblies disclosed herein.

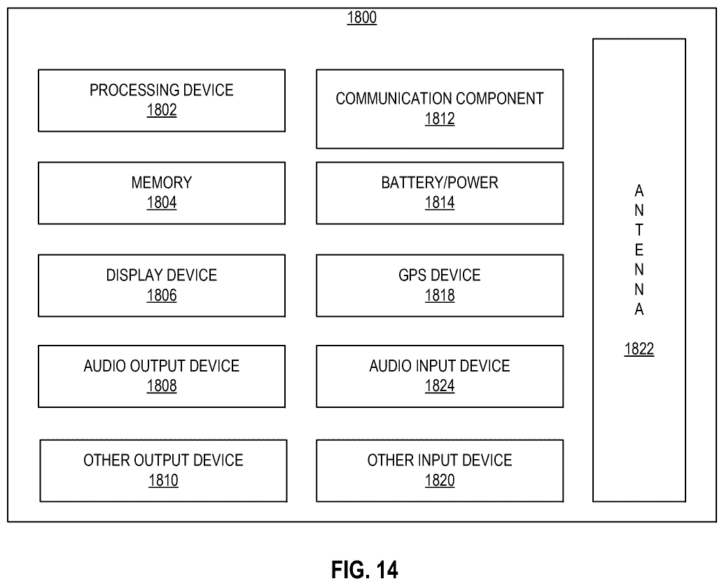

FIG. 11 is a top view of a wafer 1500 and dies 1502 that may include one or more IC structures in accordance with any of the embodiments disclosed herein. The wafer 1500 may be composed of semiconductor material and may include one or more dies 1502 having IC structures formed on a surface of the wafer 1500. Each of the dies 1502 may be a repeating unit of a semiconductor product that includes any suitable IC. After the fabrication of the semiconductor product is complete, the wafer 1500 may undergo a singulation process in which the dies 1502 are separated from one another to provide discrete “chips” of the semiconductor product. The die 1502 may include one or more IC structures as described herein (e.g., any of the structures and/or dies, or any variations thereof described herein, or any combination of such IC structures), one or more transistors and/or supporting circuitry to route electrical signals to the transistors, as well as any other IC components. In some embodiments, the wafer 1500 or the die 1502 may include a memory device (e.g., a random-access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1502. For example, a memory array formed by multiple memory devices may be formed on a same die 1502 as a processing device (e.g., the processing device 1802 of FIG. 14) or other logic that is configured to store information in the memory devices or execute instructions stored in the memory array.

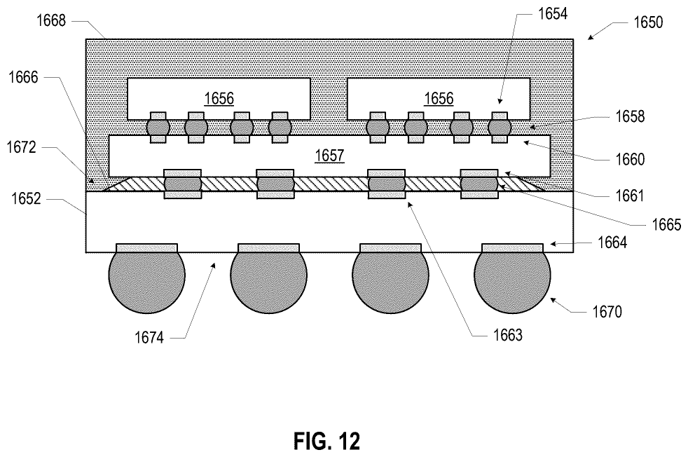

FIG. 12 is a side, cross-sectional view of an example IC package 1650 that may include one or more IC structures in accordance with any of the embodiments disclosed herein (e.g., any of the IC structures 100A, 100B, 100C, 100D, 100E, 100F, 100G, 100H, 300A, 300B, 800, 900, 1000, or any variations thereof described herein, or any combination). In some embodiments, the IC package 1650 may be a system-in-package (SiP).

The package substrate 1652 may be formed of a dielectric material (e.g., a ceramic, a buildup film, an epoxy film having filler particles therein, glass, an organic material, an inorganic material, combinations of organic and inorganic materials, embedded portions formed of different materials, etc.), and may have conductive pathways extending through the dielectric material between the face 1672 and the face 1674, or between different locations on the face 1672, and/or between different locations on the face 1674.

The package substrate 1652 may include conductive contacts 1663 that are coupled to conductive pathways (not shown) through the package substrate 1652, allowing circuitry within the dies 1656 and/or the interposer 1657 to electrically couple to various ones of the conductive contacts 1664 (or to devices included in the package substrate 1652, not shown).

The IC package 1650 may include an interposer 1657 coupled to the package substrate 1652 via conductive contacts 1661 of the interposer 1657, first-level interconnects 1665, and the conductive contacts 1663 of the package substrate 1652. The first-level interconnects 1665 illustrated in FIG. 12 are solder bumps, but any suitable first-level interconnects 1665 may be used. In some embodiments, no interposer 1657 may be included in the IC package 1650; instead, the dies 1656 may be coupled directly to the conductive contacts 1663 at the face 1672 by first-level interconnects 1665. More generally, one or more dies 1656 may be coupled to the package substrate 1652 via any suitable structure (e.g., a silicon bridge, an organic bridge, one or more waveguides, one or more interposers, wirebonds, etc.).

The IC package 1650 may include one or more dies 1656 coupled to the interposer 1657 via conductive contacts 1654 of the dies 1656, first-level interconnects 1658, and conductive contacts 1660 of the interposer 1657. The conductive contacts 1660 may be coupled to conductive pathways (not shown) through the interposer 1657, allowing circuitry within the dies 1656 to electrically couple to various ones of the conductive contacts 1661 (or to other devices included in the interposer 1657, not shown). The first-level interconnects 1658 illustrated in FIG. 12 are solder bumps, but any suitable first-level interconnects 1658 may be used. As used herein, a “conductive contact” may refer to a portion of conductive material (e.g., metal) serving as an interface between different components; conductive contacts may be recessed in, flush with, or extending away from a surface of a component, and may take any suitable form (e.g., a conductive pad or socket).

In some embodiments, an underfill material 1666 may be disposed between the package substrate 1652 and the interposer 1657 around the first-level interconnects 1665, and a mold compound 1668 may be disposed around the dies 1656 and the interposer 1657 and in contact with the package substrate 1652. In some embodiments, the underfill material 1666 may be the same as the mold compound 1668. Example materials that may be used for the underfill material 1666 and the mold compound 1668 are epoxy mold materials, as suitable. Second-level interconnects 1670 may be coupled to the conductive contacts 1664. The second-level interconnects 1670 illustrated in FIG. 12 are solder balls (e.g., for a BGA arrangement), but any suitable second-level interconnects 1670 may be used (e.g., pins in a pin grid array arrangement or lands in a land grid array arrangement). The second-level interconnects 1670 may be used to couple the IC package 1650 to another component, such as a circuit board (e.g., a motherboard), an interposer, or another IC package, as known in the art and as discussed below with reference to FIG. 11.

The dies 1656 may take the form of any of the embodiments of the die 1502 discussed herein. In embodiments in which the IC package 1650 includes multiple dies 1656, the IC package 1650 may be referred to as a multi-chip package (MCP). The dies 1656 may include circuitry to perform any desired functionality. For example, or more of the dies 1656 may be logic dies (e.g., silicon-based dies), and one or more of the dies 1656 may be memory dies (e.g., high-bandwidth memory).

Although the IC package 1650 illustrated in FIG. 12 is a flip chip package, other package architectures may be used. For example, the IC package 1650 may be a BGA package, such as an embedded wafer-level ball grid array (eWLB) package. In another example, the IC package 1650 may be a wafer-level chip scale package (WLCSP) or a panel fanout (FO) package. Although two dies 1656 are illustrated in the IC package 1650 of FIG. 12, an IC package 1650 may include any desired number of dies 1656. An IC package 1650 may include additional passive components, such as surface-mount resistors, capacitors, and inductors disposed on the first face 1672 or the second face 1674 of the package substrate 1652, or on either face of the interposer 1657. More generally, an IC package 1650 may include any other active or passive components known in the art.

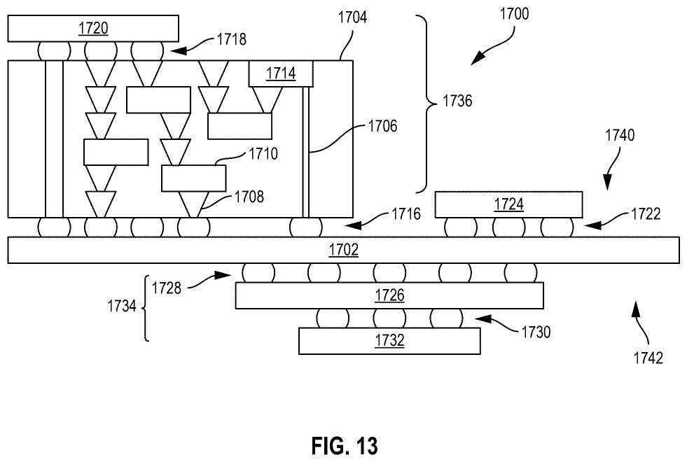

FIG. 13 is a side, cross-sectional view of an IC device assembly 1700 that may include one or more IC packages or other electronic components (e.g., a die) including one or more IC devices in accordance with any of the embodiments disclosed herein. The IC device assembly 1700 includes a number of components disposed on a circuit board 1702 (which may be, e.g., a motherboard). The IC device assembly 1700 includes components disposed on a first face 1740 of the circuit board 1702 and an opposing second face 1742 of the circuit board 1702; generally, components may be disposed on one or both faces 1740 and 1742. Any of the IC packages discussed below with reference to the IC device assembly 1700 may take the form of any of the embodiments of the IC package 1650 discussed above with reference to FIG. 12 (e.g., may include one or more of the IC structures 100A, 100B, 100C, 100D, 100E, 100F, 100G, 100H, 300A, 300B, 800, 900, 1000, or any variations thereof described herein, or any combination of such structures).

In some embodiments, the circuit board 1702 may be a PCB including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1702. In other embodiments, the circuit board 1702 may be a non-PCB substrate.

The IC device assembly 1700 illustrated in FIG. 13 includes a package-on-interposer structure 1736 coupled to the first face 1740 of the circuit board 1702 by coupling components 1716. The coupling components 1716 may electrically and mechanically couple the package-on-interposer structure 1736 to the circuit board 1702, and may include solder balls (as shown in FIG. 13), male and female portions of a socket, an adhesive, an underfill material, and/or any other suitable electrical and/or mechanical coupling structure.

The package-on-interposer structure 1736 may include an IC package 1720 coupled to a package interposer 1704 by coupling components 1718. The coupling components 1718 may take any suitable form for the application, such as the forms discussed above with reference to the coupling components 1716. Although a single IC package 1720 is shown in FIG. 13, multiple IC packages may be coupled to the package interposer 1704; indeed, additional interposers may be coupled to the package interposer 1704. The package interposer 1704 may provide an intervening substrate used to bridge the circuit board 1702 and the IC package 1720. The IC package 1720 may be or include, for example, a die (the die 1502 of FIG. 11), an IC device (e.g., one or more of the IC structures 100A, 100B, 100C, 100D, 100E, 100F, 100G, 100H, 300A, 300B, 800, 900, 1000, or any variations thereof described herein, or any combination of such structures), or any other suitable component. Generally, the package interposer 1704 may spread a connection to a wider pitch or reroute a connection to a different connection. For example, the package interposer 1704 may couple the IC package 1720 (e.g., a die) to a set of BGA conductive contacts of the coupling components 1716 for coupling to the circuit board 1702. In the embodiment illustrated in FIG. 13, the IC package 1720 and the circuit board 1702 are attached to opposing sides of the package interposer 1704; in other embodiments, the IC package 1720 and the circuit board 1702 may be attached to a same side of the package interposer 1704. In some embodiments, three or more components may be interconnected by way of the package interposer 1704.

In some embodiments, the package interposer 1704 may be formed as a PCB, including multiple metal layers separated from one another by layers of dielectric material and interconnected by electrically conductive vias. In some embodiments, the package interposer 1704 may be formed of an epoxy resin, a fiberglass-reinforced epoxy resin, an epoxy resin with inorganic fillers, a ceramic material, or a polymer material such as polyimide. In some embodiments, the package interposer 1704 may be formed of alternate rigid or flexible materials that may include the same materials described above for use in a semiconductor substrate, such as silicon, germanium, and other group III-V and group IV materials. The package interposer 1704 may include metal lines 1710 and vias 1708, including but not limited to through-silicon vias (TSVs) 1706. The package interposer 1704 may further include embedded devices 1714, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as RF devices, power amplifiers, power management devices, antennas, arrays, sensors, and microelectromechanical systems (MEMS) devices may also be formed on the package interposer 1704. The package-on-interposer structure 1736 may take the form of any of the package-on-interposer structures known in the art.

The IC device assembly 1700 may include an IC package 1724 coupled to the first face 1740 of the circuit board 1702 by coupling components 1722. The coupling components 1722 may take the form of any of the embodiments discussed above with reference to the coupling components 1716, and the IC package 1724 may take the form of any of the embodiments discussed above with reference to the IC package 1720.

The IC device assembly 1700 illustrated in FIG. 13 includes a package-on-package structure 1734 coupled to the second face 1742 of the circuit board 1702 by coupling components 1728. The package-on-package structure 1734 may include an IC package 1726 and an IC package 1732 coupled together by coupling components 1730 such that the IC package 1726 is disposed between the circuit board 1702 and the IC package 1732. The coupling components 1728 and 1730 may take the form of any of the embodiments of the coupling components 1716 discussed above, and the IC packages 1726 and 1732 may take the form of any of the embodiments of the IC package 1720 discussed above. The package-on-package structure 1734 may be configured in accordance with any of the package-on-package structures known in the art.

FIG. 14 is a block diagram of an example electrical device 1800 that may include one or more IC structures in accordance with any of the embodiments disclosed herein. For example, any suitable ones of the components of the electrical device 1800 may include one or more of the IC device assemblies 1700, IC packages 1650, or dies 1502 disclosed herein. A number of components are illustrated in FIG. 14 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single system-on-a-chip (SoC) die.

Additionally, in various embodiments, the electrical device 1800 may not include one or more of the components illustrated in FIG. 14, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded DRAM (eDRAM) or spin transfer torque magnetic random-access memory (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra-mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1812 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as global positioning system (GPS), EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include another output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra-mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

The following paragraphs provide various examples of the embodiments disclosed herein.

Example 1 provides an IC structure, including a substrate, where the substrate has a first side and a second side opposite the first side; a device region over the first side of the substrate, where the device region includes a first region and a second region coplanar with the first region, and where: a first portion of the substrate below the first region has a first thickness, where the first thickness is a dimension of the substrate in a first plane substantially orthogonal to the substrate, and a second portion of the substrate below the second region has a second thickness, where the second thickness is a dimension of the substrate in a second plane substantially orthogonal to the substrate, and the second thickness is greater than the first thickness; and a thermally conductive material over the second side of the substrate in the first plane.

Example 2 provides the IC structure of example 1, where: a ratio of the first thickness to the second thickness is in a range of about 0.2:1 to 0.9:1 (e.g., 20-90%, or 5-90%, or 30-80%).

Example 3 provides the IC structure of examples 1 or 2, where: the thermally conductive material is present over the second side of the substrate in the second plane.

Example 4 provides the IC structure of any one of examples 1-3, where: the thermally conductive material has a third thickness in the first plane (e.g., directly below the first region), the thermally conductive material has a fourth thickness in the second plane (e.g., directly below the second region), and the third thickness is greater than the fourth thickness.

Example 5 provides the IC structure of any one of examples 1-3, where: the thermally conductive material is absent in the second plane.

Example 6 provides the IC structure of any one of examples 1-5, where: the thermally conductive material includes one or more of a metal, oxygen, nitrogen, silicon, and carbon.

Example 7 provides the IC structure of any one of examples 1-6, where: the device region further includes a third region over the substrate and coplanar with the first region, where: the first device region is between the second device region and the third device region, and a third portion of the substrate below the third device region has the second thickness.

Example 8 provides the IC structure of example 7, where: the substrate includes a semiconductor material, and in a third plane substantially parallel with the substrate, a continuous portion of the thermally conductive material below the first device region is between portions of the semiconductor material.

Example 9 provides the IC structure of any one of examples 1-8, further including a third region over the substrate and coplanar with the first region, where: a third portion of the substrate has a third thickness below the third region, the third thickness is a dimension of the substrate in a third plane substantially orthogonal to the substrate, and the third thickness is different from the second thickness and different from the first thickness.

Example 10 provides the IC structure of example 9, where: the first region includes first circuitry, the second region includes second circuitry, the third region includes third circuitry, the third circuitry is different from the first circuitry and the second circuitry, and the third thickness is smaller than the first thickness and the second thickness.

Example 11 provides the IC structure of example 9, where: the third region lacks transistors, and the third thickness is greater than the first thickness and the second thickness.

Example 12 provides the IC structure of any one of examples 1-11, where: the first region includes a first transistor, the second region includes a second transistor, and the second transistor has one or more different properties relative to the first transistor.

Example 13 provides the IC structure of example 12, where: the one or more different properties include one or more of: different channel lengths, different channel materials, different doping concentrations of source or drain regions, and different gate oxide thicknesses.

Example 14 provides the IC structure of any one of examples 1-11, where: the first region includes first circuitry, the second region includes second circuitry, and the first circuitry is different from the second circuitry.

Example 15 provides the IC structure of example 14, where: the first circuitry includes a clock circuit, and the second circuitry lacks a clock circuit.

Example 16 provides the IC structure of any one of examples 1-15, where the thermally conductive material is a first thermally conductive material, and where the IC structure further includes a layer of a second thermally conductive material, where: the first thermally conductive material is between the substrate and the layer, and the first thermally conductive material has one or more of: a different material composition, a different thermal capacity, and a different thermal resistance relative to the second thermally conductive material.

Example 17 provides the IC structure of example 16, where: the layer has a substantially uniform thickness, and the second thermally conductive material has a lower thermal resistance than the first thermally conductive material.

Example 18 provides an IC structure, including a device region including a first portion with a first transistor and a second portion with a second transistor, where the second transistor has one or more different properties relative to the first transistor; a first layer including a metal; and a second layer including a semiconductor material between the device region and the first layer, where: the first portion is a first distance from the first layer, the second portion is a second distance from the first layer, and the first distance is different from the second distance.

Example 19 provides the IC structure of example 18, where: the second layer has a first thickness between the first portion and the first layer and a second thickness between the second portion and the first layer, the first thickness is a dimension of the second layer in a first plane substantially orthogonal to the device region, the second thickness is a dimension of the second layer in a second plane substantially orthogonal to the device region, and the second thickness is about 20-90% greater than the first thickness.

Example 20 provides the IC structure of examples 18 or 19, where: the second layer has alternating regions of the first thickness and the second thickness.

Example 21 provides the IC structure of any one of examples 18-20, where: the first layer has a third thickness in the first plane (e.g., directly below the first portion), the first layer has a fourth thickness in the second plane (e.g., directly below the second portion), and the third thickness is greater than the fourth thickness.

Example 22 provides the IC structure of any one of examples 18-21, where: the device region includes a third portion including a third transistor, and the third portion is a third distance from the first layer.

Example 23 provides an IC structure according to any one of examples 1-22, where the IC structure includes or is a part of a central processing unit.

Example 24 provides an IC structure according to any one of examples 1-23, where the IC structure includes or is a part of a memory device.

Example 25 provides an IC structure according to any one of examples 1-24, where the IC structure includes or is a part of a logic circuit.

Example 26 provides an IC structure according to any one of examples 1-25, where the IC structure includes or is a part of input/output circuitry.

Example 27 provides an IC structure according to any one of examples 1-26, where the IC structure includes or is a part of a field programmable gate array transceiver.

Example 28 provides an IC structure according to any one of examples 1-27, where the IC structure includes or is a part of a field programmable gate array logic.

Example 29 provides an IC structure according to any one of examples 1-28, where the IC structure includes or is a part of a power delivery circuitry.

Example 30 provides an IC package that includes an IC die including an IC structure according to any one of examples 1-29; and a further IC component, coupled to the IC die.

Example 31 provides an IC package according to example 30 where the further IC component includes a package substrate.

Example 32 provides an IC package according to example 30, where the further IC component includes an interposer.

Example 33 provides an IC package according to example 30, where the further IC component includes a further IC die.

Example 34 provides a computing device that includes a carrier substrate and an IC structure coupled to the carrier substrate, where the IC structure is an IC structure according to any one of examples 1-29, or the IC structure is included in the IC package according to any one of examples 30-33.

Example 35 provides a computing device according to example 34, where the computing device is a wearable or handheld computing device.

Example 36 provides a computing device according to examples 34 or 35, where the computing device further includes one or more communication chips.

Example 37 provides a computing device according to any one of examples 34-36, where the computing device further includes an antenna.

Example 38 provides a computing device according to any one of examples 34-37, where the carrier substrate is a motherboard.

Example 39 provides a method of fabricating an IC structure, the method including providing a preliminary IC structure including a device region over a first side of a substrate, where the device region includes a first portion with first circuitry and a second portion with second circuitry; flipping over the preliminary IC structure; providing a mask over a second side of the substrate, where the mask covers the second portion and includes an opening substantially aligned with the first portion; recessing the second side of the substrate through the opening in the mask; and providing a thermally conductive material over the recessed second side.

Example 40 provides the method of example 39, where: providing the thermally conductive material includes providing a layer of the thermally conductive material over the second side of the substrate, where the layer is thicker in a recessed region over the first portion than in a further region over the second portion.

Example 41 provides the method of any one of examples 39-40, where: providing the thermally conductive material includes providing a metal over the recessed second side.

Example 42 provides the method of any one of examples 39-41, where the mask is a first mask and the opening is a first opening, and where the method further includes after recessing the second side and prior to providing the thermally conductive material: providing a second mask over the second side, where the second mask includes a second opening, and recessing the second side of the substrate through the second opening in the second mask.

Example 43 provides a method according to any one of examples 39-42, where the IC structure is an IC structure according to any one of the preceding examples.

Example 44 provides a process of making an IC structure in accordance of any one of the preceding examples.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize. These modifications may be made to the disclosure in light of the above detailed description.

1. An integrated circuit (IC) structure, comprising:
a substrate, wherein the substrate has a first side and a second side opposite the first side;
a device region over the first side of the substrate, wherein the device region comprises a first region and a second region coplanar with the first region, and wherein:
a first portion of the substrate below the first region has a first thickness, wherein the first thickness is a first dimension of the substrate in a first plane substantially orthogonal to the substrate, and
a second portion of the substrate below the second region has a second thickness, wherein the second thickness is a second dimension of the substrate in a second plane substantially orthogonal to the substrate, and the second thickness is greater than the first thickness; and
a thermally conductive material over the second side of the substrate in the first plane.

2. The IC structure of claim 1, wherein:
a ratio of the first thickness to the second thickness is in a range of about 0.2:1 to 0.9:1.

3. The IC structure of claim 1, wherein:
the thermally conductive material is present over the second side of the substrate in the second plane.

4. The IC structure of claim 1, wherein:
the thermally conductive material has a third thickness in the first plane,
the thermally conductive material has a fourth thickness in the second plane, and
the third thickness is greater than the fourth thickness.

5. The IC structure of claim 1, wherein:
the thermally conductive material is absent in the second plane.

6. The IC structure of claim 1, wherein:
the thermally conductive material comprises one or more of a metal, oxygen, nitrogen, silicon, and carbon.

7. The IC structure of claim 1, wherein:
the device region further comprises a third region over the substrate and coplanar with the first region, wherein:
the first region is between the second region and the third region, and
a third portion of the substrate below the third region has the second thickness.

8. The IC structure of claim 7, wherein:
the substrate comprises a semiconductor material, and
in a third plane substantially parallel with the substrate, a continuous portion of the thermally conductive material below the first region is between portions of the semiconductor material.

9. The IC structure of claim 1, further comprising:
a third region over the substrate and coplanar with the first region, wherein:
a third portion of the substrate has a third thickness below the third region,
the third thickness is a dimension of the substrate in a third plane substantially orthogonal to the substrate, and
the third thickness is different from the second thickness and different from the first thickness.

10. The IC structure of claim 9, wherein:
the first region comprises first circuitry,
the second region comprises second circuitry,
the third region comprises third circuitry,
the third circuitry is different from the first circuitry and the second circuitry, and
the third thickness is smaller than the first thickness and the second thickness.

11. The IC structure of claim 9, wherein:
the third region lacks transistors, and
the third thickness is greater than the first thickness and the second thickness.

12. The IC structure of claim 1, wherein:
the first region comprises a first transistor,
the second region comprises a second transistor, and
the second transistor has one or more different properties relative to the first transistor.

13. The IC structure of claim 12, wherein:
the one or more different properties comprise one or more of:
different channel lengths, different channel materials, different doping concentrations of source or drain regions, and different gate oxide thicknesses.

14. The IC structure of claim 1, wherein:
the first region comprises first circuitry,
the second region comprises second circuitry, and
the first circuitry is different from the second circuitry.

15. The IC structure of claim 14, wherein:
the first circuitry comprises a clock circuit, and
the second circuitry lacks the clock circuit.

16. The IC structure of claim 1, wherein the thermally conductive material is a first thermally conductive material, and wherein the IC structure further comprises:
a layer of a second thermally conductive material, wherein:
the first thermally conductive material is between the substrate and the layer, and
the first thermally conductive material has one or more of:
a different material composition, a different thermal capacity, and a different thermal resistance relative to the second thermally conductive material.

17. An integrated circuit (IC) structure, comprising:
a device region comprising a first portion with a first transistor and a second portion with a second transistor, wherein the second transistor has one or more different properties relative to the first transistor;
a first layer comprising a metal; and
a second layer comprising a semiconductor material between the device region and the first layer, wherein:
the first portion is a first distance from the first layer,
the second portion is a second distance from the first layer, and
the first distance is different from the second distance.

18. The IC structure of claim 17, wherein:
the second layer has a first thickness between the first portion and the first layer and a second thickness between the second portion and the first layer,
the first thickness is a dimension of the second layer in a first plane substantially orthogonal to the device region,
the second thickness is a dimension of the second layer in a second plane substantially orthogonal to the device region, and
the second thickness is about 20-90% greater than the first thickness.

19. A method of fabricating an integrated circuit (IC) structure, the method comprising:
providing a preliminary IC structure comprising a device region over a first side of a substrate, wherein the device region comprises a first portion with first circuitry and a second portion with second circuitry;
flipping over the preliminary IC structure;
providing a mask over a second side of the substrate, wherein the mask covers the second portion and comprises an opening substantially aligned with the first portion;
recessing the second side of the substrate through the opening in the mask; and
providing a thermally conductive material over the recessed second side.

20. The method of claim 19, wherein:
providing the thermally conductive material comprises:
providing a layer of the thermally conductive material over the second side of the substrate, wherein the layer is thicker in a recessed region over the first portion than in a further region over the second portion.
